(19) United States
(12) Patent Application Publication
(10) Pub. No.: US 2025/0076360 A1
(43) Pub. Date: Mar. 6, 2025

(54) SUBSTRATE INSPECTION APPARATUS

(71) Applicant: Samsung Electronics Co., Ltd., Suwon-si (KR)

(72) Inventors: Daesung JUNG, Suwon-si (KR); Seongbeom LEE, Suwon-si (KR); Gyouil JEONG, Suwon-si (KR); Sangyoon HAN, Suwon-si (KR); Myungjoon KIM, Suwon-si (KR); Kyuhwang WON, Suwon-si (KR); Jaein JEONG, Suwon-si (KR); Hoomi CHOI, Suwon-si (KR)

(73) Assignee: Samsung Electronics Co., Ltd., Suwon-si (KR)

(21) Appl. No.: 18/823,964

(22) Filed: Sep. 4, 2024

(30) Foreign Application Priority Data
Sep. 5, 2023 (KR) 10-2023-0117895
Aug. 29, 2024 (KR) 10-2024-0116608

(51) Int. Cl. G01R 29/24; H01L 21/66; H01L 21/67; H01L 21/683; H01L 21/687

(52) U.S. Cl. CPC G01R 29/24; H01L 21/67253; H01L 21/6838; H01L 21/68742; H01L 22/14

(57) ABSTRACT

A substrate inspection apparatus includes a substrate support portion that fixedly holds a semiconductor substrate such that an upper surface and a lower surface of the semiconductor substrate are exposed; an upper inspection portion including an upper probe having a first end portion spaced apart from the upper surface, and an upper charge sensor in the first end portion that obtains an upper surface charge sensing value from the upper surface; and a lower inspection portion including a lower probe having a second end portion spaced apart from the lower surface, and a lower charge sensor in the second end portion that obtains a lower surface charge sensing value from the lower surface.

### CROSS-REFERENCE TO RELATED APPLICATIONS

This application claims priority under 35 U.S.C. § 119 to Korean Patent Application No. 10-2023-0117895, filed on Sep. 5, 2023 in the Korean Intellectual Property Office (KIPO), and Korean Patent Application No. 10-2024-0116608, filed on Aug. 29, 2024 in the Korean Intellectual Property Office (KIPO), the contents of each of which are herein incorporated by reference in their entirety.

### BACKGROUND

The present disclosure relates to substrate inspection apparatuses and substrate inspection methods. More particularly, the present disclosure relates to substrate inspection apparatuses configured to measure a charge on a surface of a semiconductor substrate and substrate inspection methods using the same.

During semiconductor manufacturing processes such as a cleaning process, a photo process, an ion implantation process, etc., surface charges may be generated on a semiconductor substrate such as a wafer. The surface charges may cause defects in the semiconductor substrate. When the surface charge is measured from one surface of the semiconductor substrate, a potential change may be induced on the other surface opposite to the one surface. In case of using Kelvin probe force microscopy, measurement consistency may be reduced due to contamination at a tip of a probe, and the tip of the probe may contact the semiconductor substrate, thereby causing defects and damaging the target surface of the semiconductor substrate. There is a problem in that it is not possible to measure surface charges on the opposite surface.

### SUMMARY

Example embodiments of the inventive concepts provide a substrate inspection apparatus that is able to simultaneously measure surface charges from an upper surface and a lower surface of a semiconductor substrate.

Example embodiments of the inventive concepts provide a substrate inspection apparatus including a substrate support portion that fixedly holds a semiconductor substrate, an upper surface and a lower surface of the semiconductor substrate are exposed while the semiconductor substrate is fixedly held by the substrate support portion; an upper inspection portion including an upper probe having a first end portion spaced apart from the upper surface, and the upper probe including an upper charge sensor in the first end portion, the upper charge sensor configured to obtain an upper surface charge sensing value from the upper surface; and a lower inspection portion including a lower probe having a second end portion spaced apart from the lower surface, and the lower probe including a lower charge sensor in the second end portion, the lower charge sensor configured to obtain a lower surface charge sensing value from the lower surface.

Example embodiments of the inventive concepts further provide a substrate inspection apparatus including a substrate support portion that fixedly holds an outer surface of a semiconductor substrate, an upper surface and a lower surface of the semiconductor substrate are exposed while the semiconductor substrate is fixedly held by the substrate support; an upper inspection portion including an upper probe having a first end portion spaced apart from the upper surface, and the upper probe including an upper charge sensor in a first central region of the first end portion, the upper charge sensor configured to obtain an upper surface charge sensing value from the upper surface; a lower inspection portion including a lower probe having a second end portion spaced apart from the lower surface, and the lower probe including a lower charge sensor in a second central region of the second end portion, the lower charge sensor configured to obtain a lower surface charge sensing value from the lower surface; and a driving portion that relatively moves the substrate support portion between the upper probe and the lower probe.

Example embodiments of the inventive concepts still further provide a substrate inspection apparatus including a substrate support portion that fixedly holds an outer surface of a semiconductor substrate, an upper surface and a lower surface of the semiconductor substrate are exposed while the semiconductor substrate is fixedly held by the substrate support portion; an upper inspection portion including an upper probe having a first end portion spaced apart from the upper surface, the upper probe movable in a horizontal direction, an upper distance sensor that measures a distance between the upper probe and the upper surface, and an upper charge sensor in a first central region of the first end portion that obtains an upper surface charge sensing value of the upper surface; a lower inspection portion including a lower probe having a second end portion spaced apart from the lower surface, the lower probe movable in the horizontal direction, a lower distance sensor that measures a distance between the lower probe and the lower surface, and a lower charge sensor in a second central region of the second end portion that obtains a lower surface charge sensing value of the lower surface; and a controller that receives and stores the upper surface charge sensing value and the lower surface charge sensing value from the upper inspection portion and the lower inspection portion respectively.

According to example embodiments, a substrate inspection apparatus may include a substrate support portion that fixedly holds a semiconductor substrate such that an upper surface and a lower surface of the semiconductor substrate are exposed; an upper inspection portion including an upper probe having a first end portion spaced apart from the upper surface, and an upper charge sensor in the first end portion that obtains an upper surface charge sensing value from the upper surface; and a lower inspection portion including a lower probe having a second end portion spaced apart from the lower surface, and a lower charge sensor in the second end portion that obtains a lower surface charge sensing value from the lower surface.

Accordingly, the substrate support portion may expose the upper surface and the lower surface of the semiconductor substrate at the same time. Since the upper surface and the lower surface of the semiconductor substrate are exposed at the same time, the upper inspection portion and the lower inspection portion may measure the upper surface charge and the lower surface charge from the upper surface and the lower surface of the semiconductor substrate through the upper charge sensor and the lower charge sensor respectively. Since the upper surface charge and the lower surface charge are measured simultaneously, a potential change due to a mutual influence between the upper surface charge and the lower surface charge that occurs between the upper surface and the lower surface during the measurement process may be calculated and reflected to increase the accuracy of the upper surface charge sensing value and the lower surface charge sensing value.

Additionally, the upper probe and the lower probe may have central regions and dummy regions surrounding the central regions, respectively. Since the upper charge sensor and the lower charge sensor are respectively provided in the central regions, a spatial resolution may be improved. Because the spatial resolution is improved, the upper charge sensor and the lower charge sensor can accurately measure the upper surface charge sensing value and the lower surface charge sensing value in a local region.

### BRIEF DESCRIPTION OF THE DRAWINGS

Example embodiments will be more clearly understood from the following detailed description taken in conjunction with the accompanying drawings. FIGS. 1 to 4 represent non-limiting, example embodiments as described herein.

FIG. 1 is a perspective view illustrating a substrate inspection apparatus in accordance with some example embodiments of the inventive concepts.

FIG. 2A is a perspective view illustrating a substrate support portion of FIG. 1.

FIG. 2B is a perspective view illustrating a substrate support in accordance with some example embodiments of the inventive concepts.

FIG. 3 is a perspective view illustrating an upper inspection portion and a lower inspection portion of FIG. 1.

FIG. 4 is an enlarged view illustrating a portion ‘A’ in FIG. 3.

FIG. 5 is a block diagram illustrating an upper charge sensor of an upper inspection portion of FIG. 4.

FIG. 6 is a side view illustrating a substrate inspection apparatus in accordance with some example embodiments of the inventive concepts.

FIG. 7 is a cross-sectional view illustrating a substrate inspection apparatus in accordance with some example embodiments of the inventive concepts.

FIG. 8 is a plan view illustrating a semiconductor substrate on a substrate support portion of FIG. 7.

FIG. 9 is a cross-sectional view illustrating a substrate inspection method in accordance with some example embodiments of the inventive concepts.

FIGS. 10A and 10B are plan views illustrating a scan direction in the substrate inspection method of FIG. 9.

FIGS. 11A and 11B are cross-sectional views illustrating a substrate inspection method in accordance with some example embodiments of the inventive concepts.

FIGS. 12A and 12B are cross-sectional views illustrating a substrate inspection method in accordance with some example embodiments of the inventive concepts.

### DETAILED DESCRIPTION

Hereinafter, example embodiments will be explained in detail with reference to the accompanying drawings.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

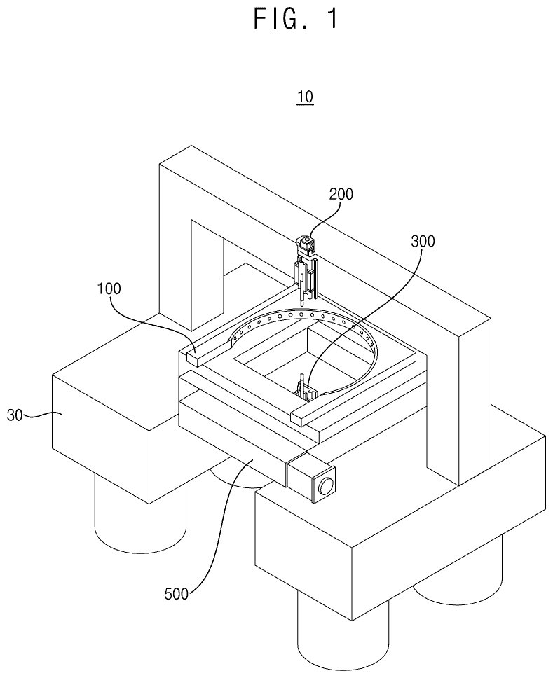

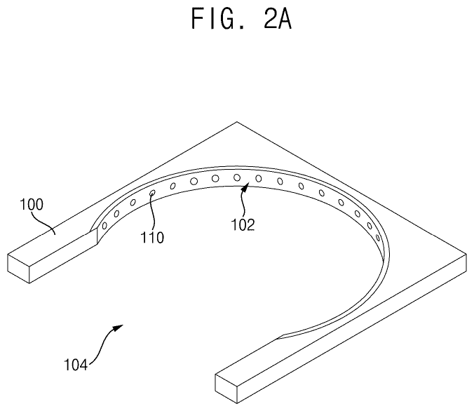

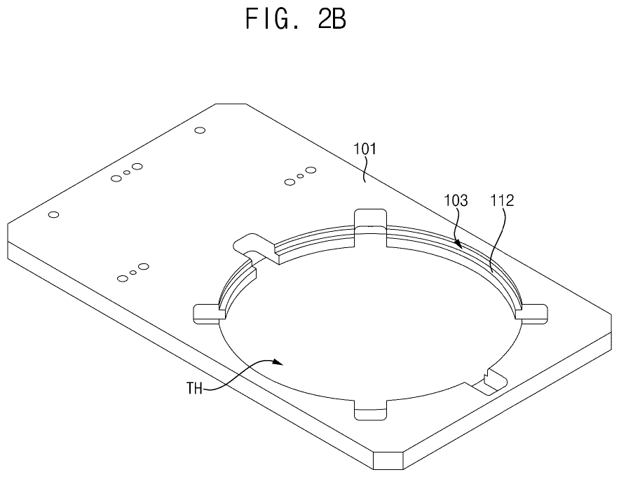

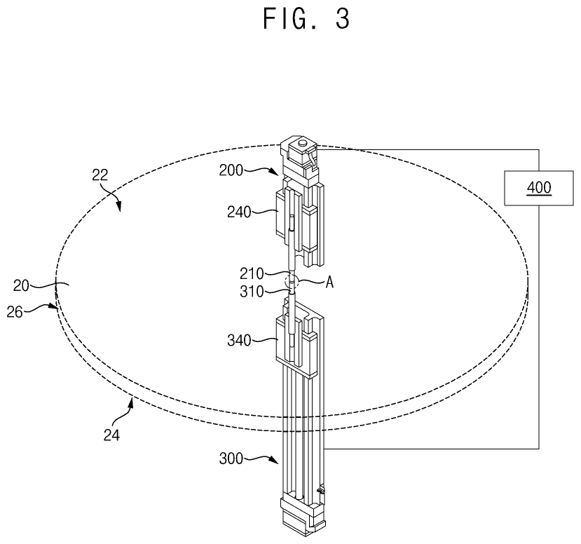

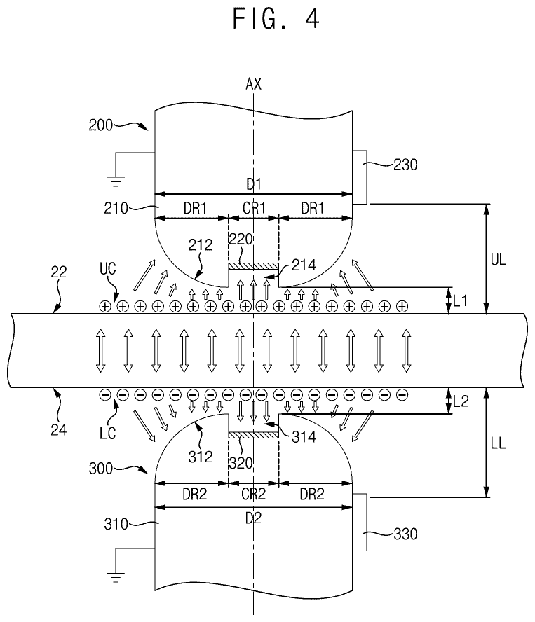

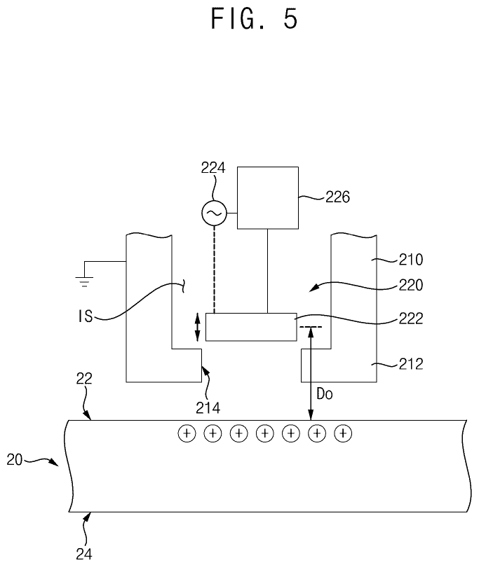

FIG. 1 is a perspective view illustrating a substrate inspection apparatus in accordance with example embodiments of the inventive concepts. FIG. 2A is a perspective view illustrating a substrate support portion of FIG. 1. FIG. 2B is a perspective view illustrating a substrate support in accordance with some example embodiments of the inventive concepts. FIG. 3 is a perspective view illustrating an upper inspection portion and a lower inspection portion of FIG. 1. FIG. 4 is an enlarged view illustrating a portion ‘A’ in FIG. 3. FIG. 5 is a block diagram illustrating an upper charge sensor of an upper inspection portion of FIG. 4.

Referring to FIGS. 1 to 5, a substrate inspection apparatus 10 may include a substrate support portion 100 configured to hold a semiconductor substrate 20, an upper inspection portion 200 configured to measure an upper surface charge from an upper surface 22 of the semiconductor substrate, and a lower inspection portion 300 configured to measure a lower surface charge from a lower surface 24 of the semiconductor substrate 20. The substrate inspection apparatus 10 may further include a table 30 configured to fixedly mount the substrate support portion 100, the upper inspection portion 200, and the lower inspection portion 300 on the ground.

In some example embodiments, the substrate inspection apparatus 10 may measure a surface charge from the semiconductor substrate 20. The surface charge may cause electrical effects such as electrostatic particle adsorption, electrostatic discharge (ESD), arcing, etc. on the semiconductor substrate 20. The surface charge may generate the electrical effect on the semiconductor substrate 20, thereby causing a defect in the semiconductor substrate 20. Additionally, the surface charge may cause the wafer to stick to an electrostatic chuck.

The substrate inspection apparatus 10 may measure the surface charge from the semiconductor substrate 20 during a series of semiconductor manufacturing processes. For example, the semiconductor manufacturing processes may include a cleaning process, a photo process, a development process, etc. The substrate inspection apparatus 10 may measure the surface charge during the semiconductor manufacturing processes to thereby improve the reliability of the semiconductor device.

In some example embodiments, the substrate support portion 100 may temporarily fix the semiconductor substrate 20. During the process of measuring the surface charge, the substrate support portion 100 may stably support the semiconductor substrate 20. The substrate support portion 100 may be fixed on the table 30.

The substrate support portion 100 may fixedly hold an outer surface 26 of the semiconductor substrate 20. For example, the outer surface 26 may be an outer sidewall surface of the semiconductor substrate 20. Since the substrate support portion 100 holds the outer surface 26 of the semiconductor substrate 20, the substrate support portion 100 may simultaneously expose the upper surface 22 and the lower surface 24 of the semiconductor substrate 20. Since the substrate support portion 100 simultaneously exposes the upper surface 22 and the lower surface 24 of the semiconductor substrate 20, the upper inspection portion 200 and the lower inspection portion 300 may simultaneously measure the surface charge from the upper surface 22 and the lower surface 24 of the semiconductor substrate 20.

As illustrated in FIG. 2A, the substrate support portion 100 may include a plurality of vacuum holes 110 provided in an inner surface 102 to temporarily fix the outer surface 26 of the semiconductor substrate 20 and a plurality of vacuum inlet lines (not shown) that apply vacuum pressure to the vacuum holes 110. The substrate support portion 100 may include a material having sufficient strength and rigidity to withstand the vacuum pressure. The vacuum inlet lines may be connected to a vacuum generator (not shown) that generates the vacuum pressure. The plurality of vacuum holes 110 may be arranged to be spaced apart from each other along the inner surface 102 of the substrate support portion 100.

The substrate support portion 100 may have a side opening 104 that is opened to the outside. The semiconductor substrate 20 may be placed on the substrate support portion 100 through a robot arm. The robot arm may move through the side opening 104 to place the semiconductor substrate 20 on the substrate support portion 100. The robot arm may support the lower surface 24 of the semiconductor substrate 20 and may move to the side opening 104 in the vertical direction to place the semiconductor substrate 20 within the inner surface of the substrate support portion 100.

As illustrated in FIG. 2B, the substrate support portion 101 may mount and hold the semiconductor substrate 20. The substrate support portion 101 may have a substrate holder for holding the semiconductor substrate 20. The substrate holder may include a support plate having a through hole TH for receiving the semiconductor substrate 20 and a step portion 112 extending along an inner surface 103 of the through hole TH. Portions of an outer sidewall surface of the semiconductor substrate 20 may be supported on the step portion 112, and the substrate support portion 101 may support at least portions (e.g., three-point support) of the lower surface 24 of the semiconductor substrate 20 through the step portion 112.

In addition, a plurality of vacuum holes (not shown) may be provided in an upper surface of the step portion 112 to apply vacuum pressure in order to temporarily fix the semiconductor substrate 20. The plurality of vacuum holes may be arranged to be spaced apart from each other along the upper surface of the step portion 112. The plurality of vacuum holes may be respectively connected to a plurality of vacuum inlet lines (not shown), and the vacuum inlet lines may be connected to a vacuum generator (not shown) to receive the vacuum pressure.

In some example embodiments, the upper inspection portion 200 may include an upper probe 210 having a first end portion 212, and an upper charge sensor 220 to obtain an upper surface charge sensing value from the upper surface 22 of the semiconductor substrate 20. The upper inspection portion 200 may further include an upper distance sensor 230 to measure an upper spacing distance UL from the upper surface 22 of the semiconductor substrate 20. The upper inspection portion 200 may further include an upper vertical driver 240 to move the upper probe 210 in a vertical direction.

The upper probe 210 may have a rod shape extending in the vertical direction over the semiconductor substrate 20. The upper probe 210 may be provided over the semiconductor substrate 20 such that the first end portion 212 faces the upper surface 22 of the semiconductor substrate 20. The upper probe 210 may be movable in a horizontal direction over the upper surface 22 of the semiconductor substrate 20.

The upper probe 210 may be grounded to the ground. Since the upper probe 210 is grounded to the ground, upper charges UC formed on the upper surface 22 of the semiconductor substrate 20 may have an upper potential difference from the first end portion 212 of the upper probe 210. The upper charges UC may generate an electrical reaction with the first end portion 212 of the upper probe 210 due to the upper potential difference. The upper charges UC may include charges at a portion having a certain depth from the upper surface of the semiconductor substrate 20. For example, the upper charges UC may be charges within a depth of about 200 μm from the upper surface of the semiconductor substrate 20.

The first end portion 212 of the upper probe 210 may have a first central region CR1 and a first dummy region DR1 surrounding the first central region CR1. The first end portion 212 of the upper probe 210 may make the electrical reaction with the upper charges UC of the semiconductor substrate 20 on the first dummy region DR1.

The first end portion 212 of the upper probe 210 may have a first curvature in the first dummy region DR1. When the upper probe 210 moves over the upper surface 22 of the semiconductor substrate 20, the upper probe 210 may be limited and/or prevented from causing damage to the semiconductor substrate 20 through the first curvature. Since the first end portion 212 of the upper probe 210 has the first curvature, even when the first end portion 212 collides with the semiconductor substrate 20 where warpage has occurred, the impact may be alleviated or reduced. For example, the first curvature may be within a range of 1 mm to 100 mm.

The upper charge sensor 220 may obtain an upper charge sensing value (e.g., charge amount, electric field intensity, or potential difference) from the upper surface 22 of the semiconductor substrate 20. The upper charge sensor 220 may make an electrical reaction with the upper charges UC formed on the upper surface 22 of the semiconductor substrate 20. For example, the upper charge sensor 220 may include a capacitor structure to form an upper capacitor together with the semiconductor substrate as an object and an actuator to modulate a capacitance of the upper capacitor, and the upper charge sensor 220 may obtain an electric field intensity or potential difference with the upper charges UC through the upper capacitor. The upper charge value may be calculated (e.g., determined) through the electric field intensity or potential difference obtained by the upper charge sensor 220.

The upper charge sensor 220 may be provided in the first central region CR1 in the first end portion 212 of the upper probe 210. Because the first end portion 212 of the upper probe 210 makes the electrical reaction with the upper charges UC in the first dummy region DR1, the upper charge sensor 220 may obtain the upper charge sensing value for the upper charges UC positioned in the first central region CR1. Because the upper charge sensor 220 obtains the upper charge sensing value in the first central region CR1, a spatial resolution of the upper charge sensor 220 may be improved. Because the spatial resolution of the upper charge sensor 220 is improved, the upper charge sensor 220 may detect the upper charge value in a local region.

The upper probe 210 may have a first cavity 214 provided in the first central region CR1 of the first end portion 212. The upper charge sensor 220 may be provided in the first cavity 214. Since the upper charge sensor 220 is provided in the first cavity 214, the upper charge sensor 220 may obtain the upper charge sensing value for the upper charges UC positioned in the first central region CR1. The upper charge sensor 220 may obtain the upper charge sensing value in the local region through the first cavity 214.

The upper charge sensor 220 may improve the spatial resolution through the first dummy region DR1. The upper charge sensor 220 may improve the spatial resolution through the first cavity 214. The spatial resolution may be determined based on the upper charge sensing value that is obtained from the upper charges UC within the local region.

As illustrated in FIG. 5, the upper probe 210 may include a housing structure that has an accommodation space IS for accommodating at least a portion of the upper charge sensor 220. The housing structure may be a shielding structure that surround the at least a portion of the upper charge sensor 220 in the accommodation space IS. The housing structure may include a metallic material such as stainless steel. The upper charge sensor 220 may include a vibrating capacitive sensor.

For example, the upper charge sensor 220 may include a vibrating electrode type field meter. A sensing electrode 222 of the upper charge sensor 220 may be exposed through the first cavity 214 of the upper probe 210, and the exposed sensing electrode 222 and the upper surface 22 of the semiconductor substrate 20 may be modeled as a parallel-plate capacitor. The sensing electrode 222 may vibrate in a direction orthogonal to the upper surface 22 of the semiconductor substrate 20 by an actuator 224, and an electric current I flowing through the sensing electrode 222 may be proportional to the value of the electric potential present on the upper surface 22 of the semiconductor substrate 20. The current I flowing through the sensing electrode 222 may be expressed by following Equation (1).

$$I = U \cdot \frac{dC}{dt} = U \cdot \frac{d}{dt} ( \frac{{ϵϵ}_{0} A}{{D}_{0} + {D}_{1} sin ( ω t )} ) = - U \cdot {ϵϵ}_{0} A \cdot \frac{{D}_{1} ωcos ( ω t )}{{[ {D}_{0} + {D}_{1} sin ( ω t ) ]}^{2}} \qquad Equation ( 1 )$$

Here, U is the potential difference between the tested surface and the vibrating sensing electrode [V], D₀ is a constant representing the gap between the sensing electrode and the tested surface when the sensing electrode is not vibrating [m], D₁ is the amplitude of vibrations [m], ω is the frequency of vibrations (ω=2πf) [rad/s], where f is a frequency in [Hz], A is the surface area of the sensing electrode [m²], ε is the relative electric permittivity of the material between the sensing electrode and the tested surface (ε≈1 for air), and co is the electric permittivity of vacuum (8.85·10⁻¹² [F/m]).

The current I flowing through the sensing electrode 222 may be amplified and demodulated by a sensing circuitry 234 including a phase-sensitive demodulator circuit to produce a voltage proportional to the amplitude of the current. The upper charge sensing value may be calculated using the generated voltage obtained by the vibrating capacitive sensor of the upper inspection portion 200.

As another example, the upper charge sensor 220 may include a stationary electrode type field meter. A sensing electrode of the upper charge sensor 220 may be fixedly disposed to be exposed through the first cavity 214 of the upper probe 210, and the exposed sensing electrode and the upper surface 22 of the semiconductor substrate 20 may be modeled as a parallel-plate capacitor. An aperture modulation portion may be provided on the exposed surface of the sensing electrode. The aperture modulation portion may include a plurality of aperture plates defining an aperture that exposes a portion of the exposed surface of the sensing electrode. The aperture plates may vibrate in a direction parallel to the surface of the sensing electrode by an actuator to change an area of the aperture according to a vibration frequency. The aperture plates may be grounded, and as the aperture area changes, an electric field applied to the sensing electrode through the aperture may change, thereby changing an electric current flowing through the sensing electrode. The upper charge sensing value may be calculated by detecting the current flowing through the sensing electrode or a voltage between the sensing electrode and the tested surface.

As illustrated in FIG. 4, the first end portion 212 of the upper probe 210 may have a first diameter D1. The upper probe 210 having the first diameter D1 may move in the horizontal direction without restriction. The upper probe 210 may sufficiently generate the electrical reaction with the upper charges UC in the first dummy region DR1 through the first diameter D1. The first diameter D1 may be within an optimized diameter range for the upper charge sensor 220 to obtain the upper charge sensing value. For example, the first diameter D1 may be within a range of 1 mm to 30 mm.

The upper distance sensor 230 may obtain the upper spacing distance UL from the upper surface 22 of the semiconductor substrate 20. The upper distance sensor 230 may calculate (e.g., determine) a distance between the upper surface 22 of the semiconductor substrate 20 and the first end portion 212 based on the upper spacing distance UL. Alternatively, the upper distance sensor 230 may calculate (e.g., determine) the distance between the upper surface 22 of the semiconductor substrate 20 and the upper distance sensor 230 based on the upper spacing distance UL. For example, the upper distance sensor 230 may measure a distance between the upper surface 22 and the upper charge sensor 220.

For example, the upper distance sensor 230 may include a confocal chromatic sensor, an interferometric displacement sensor, a laser displacement sensor, etc. The confocal chromatic sensor may accurately calculate (e.g., determine) the upper spacing distance UL even when light is reflected from the upper surface 22 of the semiconductor substrate 20.

The upper vertical driver 240 may move the upper probe 210 in the vertical direction. The upper vertical driver 240 may move the upper charge sensor 220 and the upper distance sensor 230 provided on the upper probe 210 in the vertical direction.

The upper vertical driver 240 may space the first end portion 212 apart from the upper surface 22 of the semiconductor substrate 20 by a first distance L1 based on the upper spacing distance UL that is calculated from the upper distance sensor 230. When the first end portion 212 is positioned within the first distance L1, the upper vertical driver 240 may stop the movement of the upper probe 210. The first distance L1 may be an optimal distance for the upper charge sensor 220 to obtain the upper charge sensing value. For example, the first distance L1 may be within a range of 10 μm to 5 mm.

In some example embodiments, the lower inspection portion 300 may include a lower probe 310 having a second end portion 312, and a lower charge sensor 320 to obtain a lower surface charge sensing value from the lower surface 24 of the semiconductor substrate 20. The lower inspection portion 300 may further include a lower distance sensor 330 to measure a lower spacing distance LL from the lower surface 24 of the semiconductor substrate 20. The lower inspection portion 300 may further include a lower vertical driver 340 to move the lower probe 310 in the vertical direction.

The lower probe 310 may have a rod shape extending in the vertical direction under the semiconductor substrate 20. The lower probe 310 may be provided under the semiconductor substrate 20 such that the second end portion 312 faces the lower surface 24 of the semiconductor substrate 20. The lower probe 310 may be movable in a horizontal direction under the lower surface 24 of the semiconductor substrate 20.

The lower probe 310 may be grounded to the ground. Since the lower probe 310 is grounded to the ground, lower charges LC formed on the lower surface 24 of the semiconductor substrate 20 may have a lower potential difference from the second end portion 312 of the lower probe 310. The lower charges LC may generate an electrical reaction with the second end portion 312 of the lower probe 310 due to the lower potential difference. The lower charges LC may include charges at a portion having a certain depth from the lower surface of the semiconductor substrate 20. For example, the lower charges LC may be charges within a depth of about 200 μm from the lower surface of the semiconductor substrate 20.

The lower probe 310 may be provided on the same axis AX as the upper probe 210. Since the lower probe 310 and the upper probe 210 are provided on the same axis AX, the upper charge sensor 220 and the lower charge sensor 320 may simultaneously measure an upper surface charge and a lower surface charge respectively from the upper surface 22 and the lower surface 24 of the semiconductor substrate 20. Since the lower probe 310 and the upper probe 210 are provided on the same axis AX, the substrate inspection apparatus 10 may determine the influence relationship between the upper surface charge and the lower surface charge through the upper charge sensor 220 and the lower charge sensor 320.

Alternatively, the lower probe 310 may not be provided on the same axis AX as the upper probe 210. In this case, the upper probe 210 and the lower probe 310 may measure the upper surface sensing charge and the lower surface sensing charge, respectively, from the upper surface 22 and the lower surface 24 of the semiconductor substrate 20 at different locations.

The second end portion 312 of the lower probe 310 may have a second central region CR2 and a second dummy region DR2 surrounding the second central region CR2. The second end portion 312 of the lower probe 310 may make the electrical reaction with the lower charges LC of the semiconductor substrate 20 on the second dummy region DR2.

The second end portion 312 of the lower probe 310 may have a second curvature in the second dummy region DR2. When the lower probe 310 moves under the lower surface 24 of the semiconductor substrate 20, the lower probe 310 may be limited and/or prevented from causing damage to the semiconductor substrate 20 through the second curvature. Since the second end portion 312 of the lower probe 310 has the second curvature, even when the second end portion 312 collides with the semiconductor substrate 20 where warpage has occurred, the impact may be alleviated or reduced. For example, the second curvature may be within a range of 1 mm to 100 mm. The second curvature of the end portion of the lower probe may be determined in consideration of the degree of warpage of the semiconductor substrate.

The lower charge sensor 320 may obtain a lower charge sensing value (e.g., charge amount, electric field intensity, or potential difference) from the lower surface 24 of the semiconductor substrate 20. The lower charge sensor 320 may make the electrical reaction with the lower charges LC formed on the lower surface 24 of the semiconductor substrate 20. For example, the lower charge sensor 320 may have a capacitor structure to form a lower capacitor together with the semiconductor substrate as an object and an actuator to modulate a capacitance of the lower capacitor, and the lower charge sensor 320 may obtain a lower potential difference with the lower charges LC through the lower capacitor. The lower charge value can be calculated (e.g., determined) based on the electric field intensity or potential difference obtained by the lower charge sensor 320.

The lower charge sensor 320 may be provided in the second central region CR2 in the second end portion 312 of the lower probe 310. Because the second end portion 312 of the lower probe 310 makes the electrical reaction with the lower charges LC in the second dummy region DR2, the lower charge sensor 320 may obtain the lower charge sensing value for the lower charges LC positioned in the second central region CR2. Because the lower charge sensor 320 obtains the lower charge sensing value in the second central region CR2, a spatial resolution of the lower charge sensor 320 may be improved. Because the spatial resolution of the lower charge sensor 320 is improved, the lower charge sensor 320 may detect the lower charge sensing value in a local region.

The lower probe 310 may have a second cavity 314 provided in the second central region CR2 of the second end portion 312. The lower charge sensor 320 may be provided in the second cavity 314. Since the lower charge sensor 320 is provided in the second cavity 314, the lower charge sensor 320 may obtain the lower charge sensing value for the lower charges LC positioned in the second central region CR2. The lower charge sensor 320 may obtain the lower charge value in the local region through the second cavity 314.

Similarly to the upper probe 210, the lower probe 310 may include a housing structure that has an accommodation space for accommodating at least a portion of the lower charge sensor 320. The housing structure may be a shielding structure that surrounds at least the portion of the lower charge sensor 320 in the accommodation space. The housing structure may include a metallic material such as stainless steel. The lower charge sensor 320 may include a vibrating capacitive sensor. For example, the lower charge sensor 320 may include a vibrating electrode type filed meter or a stationary electrode type filed meter.

The lower charge sensor 320 may improve the spatial resolution through the second dummy region DR2. The lower charge sensor 320 may improve the spatial resolution through the second cavity 314. The spatial resolution may be determined based on the lower charge sensing value that is obtained from the lower charges LC within the local region.

The second end portion 312 of the lower probe 310 may have a second diameter D2. The lower probe 310 having the second diameter D2 may move in a horizontal direction without restriction. The lower probe 310 may sufficiently generate the electrical reaction with the lower charges LC in the second dummy region DR2 through the second diameter D2. The second diameter D2 may be within an optimized diameter range for the lower charge sensor 320 to obtain the lower charge sensing value. For example, the second diameter D2 may be within a range of 1 mm to 30 mm.

The lower distance sensor 330 may obtain the lower spacing distance LL from the lower surface 24 of the semiconductor substrate 20. The lower distance sensor 330 may calculate (e.g., determine) a distance between the lower surface 24 of the semiconductor substrate 20 and the second end portion 312 based on the lower spacing distance LL. Alternatively, the lower distance sensor 330 may calculate (e.g., determine) the distance between the lower surface 24 of the semiconductor substrate 20 and the lower distance sensor 330 based on the lower spacing distance LL. For example, the lower distance sensor 330 may measure a distance between the lower surface 24 and the lower charge sensor 320. For example, lower distance sensor 330 may include a confocal displacement sensor.

The lower vertical driver 340 may move the lower probe 310 in the vertical direction. The lower vertical driver 340 may move the lower charge sensor 320 and the lower distance sensor 330 provided on the lower probe 310 in the vertical direction. The lower vertical driver 340 may move the lower probe 310 in the vertical direction at the same time as the upper vertical driver 240. The upper probe 210 and the lower probe 310 may simultaneously move adjacent to the semiconductor substrate 20 by the upper vertical driver 240 and the lower vertical driver 340.

The lower vertical driver 340 may space the second end portion 312 apart from the lower surface 24 of the semiconductor substrate 20 by a second distance L2 based on the lower spacing distance LL that is calculated from the lower distance sensor 330. When the second end portion 312 is positioned within the second distance L2, the lower vertical driver 340 may stop the movement of the lower probe 310. The second distance L2 may be an optimal distance for the lower charge sensor 320 to obtain the lower charge value. For example, the second distance L2 may be within a range of 10 μm to 5 mm.

In some example embodiments, the substrate inspection apparatus 10 may further include a controller 400 configured to transmit control signals to the upper inspection portion 200 and the lower inspection portion 300. The controller 400 may receive the upper surface charge sensing value from the upper inspection portion 200. The controller 400 may receive the lower surface charge sensing value from the lower inspection portion 300. The controller 400 may store the upper surface charge sensing value and the lower surface charge sensing value.

The controller 400 may store an algorithm for correcting the upper surface charge sensing value and the lower surface charge sensing value. The controller 400 may increase the accuracy of the upper surface charge sensing value and the lower surface charge sensing value through the algorithm.

The controller 400 may respectively correct the upper surface charge sensing value and the lower surface charge sensing value through the algorithm. The controller 400 may respectively correct the upper surface charge sensing value and the lower surface charge sensing value based on the influence relationship between the upper surface charge and the lower surface charge through the algorithm.

The controller 400 may correct the lower surface charge sensing value based on the upper surface charge sensing value. The controller 400 may correct the upper surface charge sensing value based on the lower surface charge sensing value. The corrected upper surface charge sensing value Qu may be defined by Equation (2-1) below, and the corrected lower surface charge sensing value Ql may be defined by Equation (2-2) below.

$${Q}_{u} = {K}_{1} {Q}_{1} + {K}_{2} {Q}_{2} \qquad Equation ( 2 - 1 )$$

$${Q}_{l} = {K}_{2} {Q}_{1} + {K}_{1} {Q}_{2} \qquad Equation ( 2 - 2 )$$

Here, Qu is the corrected upper surface charge sensing value, Ql is the corrected lower surface charge sensing value, Q1 is the upper surface charge sensing value measured from the upper charge sensor, Q2 is the lower surface charge sensing value measured from the lower charge sensor, and K1 and K2 are constants. The sum of K1 and K2 is 1.

The upper surface charge sensing value and the lower surface charge sensing value may be corrected by the above-described simultaneous equations (2-1, 2-2). However, it may not be limited thereto, and for example, the upper surface charge sensing value and the lower surface charge sensing value may be corrected by a nonlinear equation or an equation that reflects the results of multiple measurements at different distances.

The controller 400 may correct the upper surface charge sensing value based on the influence relationship between the first central region CR1 and the first dummy region DR1 through the algorithm. When the upper probe 210 moves over the upper surface 22 of the semiconductor substrate 20, the upper charges UC formed in the first central region CR1 and the first dummy region DR1 may influence each other. The controller 400 may correct the upper surface charge sensing value by reflecting the influence relationship between the first central region CR1 and the first dummy region DR1 through a distribution similar to a Gaussian distribution.

The controller 400 may correct the lower surface charge sensing value by reflecting the influence relationship between the second central region CR2 and the second dummy region DR2 through the distribution.

In some example embodiments, the substrate inspection apparatus 10 may further include a first driving portion 500 that moves the substrate support portion 100.

The first driving portion 500 may move the substrate support portion 100 that supports the semiconductor substrate 20 in the horizontal direction. The first driving portion 500 may move the semiconductor substrate 20 between the upper inspection portion 200 and the lower inspection portion 300 through the substrate support portion 100. The first driving portion 500 may move the substrate support portion 100 in a first horizontal direction and a second horizontal direction perpendicular to the first horizontal direction.

When the first driving portion 500 moves the substrate support portion 100 in the horizontal direction, the upper probe 210 and the lower probe 310 may be fixed at preset positions. The first driving portion 500 may move the semiconductor substrate 20 in the horizontal direction through the substrate support portion 100 between the fixed upper probe 210 and lower probe 310. The upper inspection portion 200 and the lower inspection portion 300 may measure the upper surface charge and the lower surface charge from the semiconductor substrate 20 that moves in the horizontal direction through the first driving portion 500.

In some example embodiments, the substrate inspection apparatus 10 may further include a second driving portion (not shown) that moves the upper inspection portion 200 and the lower inspection portion 300. The second driving portion may move the upper probe 210 and the lower probe 310 in the horizontal direction with the semiconductor substrate 20 interposed therebetween.

When the second driving portion moves the upper probe 210 and the lower probe 310 in the horizontal direction, the substrate support portion 100 that holds the semiconductor substrate 20 may be fixed at a preset position. The second driving portion may move the upper probe 210 over the fixed semiconductor substrate 20 and the lower probe 310 under the fixed semiconductor substrate 20 in the horizontal direction. While moving the upper inspection portion 200 and the lower inspection portion 300 in the horizontal direction through the second driving portion, the upper surface charge and the lower surface charge from the semiconductor substrate 20 may be measured.

As described above, the substrate support portion 100 may expose the upper surface 22 and the lower surface 24 of the semiconductor substrate 20 at the same time. Since the upper surface 22 and the lower surface 24 of the semiconductor substrate 20 are exposed at the same time, the upper inspection portion 200 and the lower inspection portion 300 may measure the upper surface charge and the lower surface charge from the upper surface 22 and the lower surface 24 of the semiconductor substrate 20 through the upper charge sensor 220 and the lower charge sensor 320 respectively. Since the upper surface charge and the lower surface charge are measured simultaneously, the potential change due to the mutual influence between the upper surface charge and the lower surface charge that occurs between the upper surface 22 and the lower surface 24 during the measurement process may be reflected to increase the accuracy of the upper surface charge sensing value and the lower surface charge sensing value.

Additionally, the upper probe 210 and the lower probe 310 may have the central regions CR1 and CR2 and the dummy regions DR1 and DR2 surrounding the central regions CR1 and CR2, respectively. Since the upper charge sensor 220 and the lower charge sensor 320 are respectively provided in the central regions CR1 and CR2, the spatial resolution may be improved. Because the spatial resolution is improved, the upper charge sensor 220 and the lower charge sensor 320 can accurately measure the upper surface charge sensing value and the lower surface charge sensing value in the local region.

Accordingly, example embodiments of the inventive concepts provide a substrate inspection apparatus that is configured to measure upper surface charge sensing values and lower surface charge sensing values respectively from an upper surface and a lower surface of a semiconductor substrate at a same time without contacting the upper and lower surfaces of the semiconductor substrate, that is configured to correct the measured upper and lower charge sensing values, and that is configured to reduce/prevent defects in the semiconductor substrate to thus provide a manufacturing process that produces higher quality chips.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, an application-specific integrated circuit (ASIC), etc.

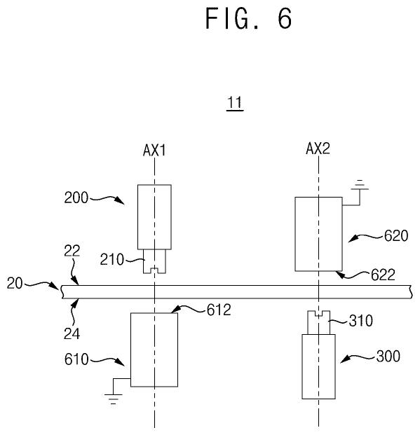

FIG. 6 is a side view illustrating a substrate inspection apparatus in accordance with some example embodiments of the inventive concepts. The substrate inspection apparatus may be substantially the same as or similar to the substrate inspection apparatus described with reference to FIGS. 1 to 5 except for additional first and second dummy probes. Thus, same reference numerals will be used to refer to the same or like elements and any further repetitive explanation concerning the above elements will be omitted.

Referring to FIG. 6, a substrate inspection device 11 may include a substrate support portion configured to hold a semiconductor substrate 20, an upper inspection portion 200 configured to measure an upper surface charge from an upper surface 22 of the semiconductor substrate 20, a lower inspection portion 300 configured to measure a lower surface charge from a lower surface 24 of the semiconductor substrate 20, a first dummy probe 610 under the semiconductor substrate 20 to correspond to the upper inspection portion 200, and a second dummy probe 620 over the semiconductor substrate 20 to correspond to the lower inspection portion 300.

In some example embodiments, a lower probe 310 of the lower inspection portion 300 may not be provided on the same axis as an upper probe 210 of the upper inspection portion 200. The upper probe 210 and the lower probe 310 may measure an upper surface sensing charge and a lower surface sensing charge, respectively, from the upper surface and the lower surface of the semiconductor substrate at different locations.

In some example embodiments, the first dummy probe 610 may be provided under the semiconductor substrate 20 and may include a ground structure having a plate or rod shape. The first dummy probe 610 may be provided under the semiconductor substrate 20 such that a first distal end 612 thereof faces the lower surface 24 of the semiconductor substrate 20. The first distal end 612 of the first dummy probe 610 may have a size corresponding to a size of a first end portion of the upper probe 210 of the upper inspection portion 200.

The first dummy probe 610 may be provided to correspond to the upper probe 210 of the upper inspection portion 200. The first dummy probe 610 may be provided on the same axis AX1 as the upper probe 210. The first dummy probe 610 may be movable in a horizontal direction on the lower surface 24 of the semiconductor substrate 20. When the upper probe 210 moves in the horizontal direction, the first dummy probe 610 may also move in the horizontal direction together with the upper probe 210.

The first dummy probe 610 may be grounded to the ground. When the upper inspection portion 200 obtains the upper charge sensing value from the upper surface 22 of the semiconductor substrate 20, the first dummy probe 610 may increase the signal-to-noise ratio (SNR) of the upper inspection portion 200 caused by charges on the lower surface 24 of the semiconductor substrate 20.

In some example embodiments, the second dummy probe 620 may be provided above the semiconductor substrate 20 and may include a ground structure having a plate or rod shape. The second dummy probe 620 may be provided over the semiconductor substrate 20 such that a second distal end 622 thereof faces the upper surface 22 of the semiconductor substrate 20. The second distal end 622 of the second dummy probe 620 may have a size corresponding to a size of a second end portion of the lower probe 310 of the lower inspection portion 300.

The second dummy probe 620 may be provided to correspond to the lower probe 310 of the lower inspection portion 300. The second dummy probe 620 may be provided on the same axis AX2 as the lower probe 310. The second dummy probe 620 may be movable in the horizontal direction on the upper surface 22 of the semiconductor substrate 20. When the lower probe 310 moves in the horizontal direction, the second dummy probe 620 may also move in the horizontal direction together with the lower probe 310.

The second dummy probe 620 may be grounded to the ground. When the lower inspection portion 300 obtains the lower charge sensing value from the lower surface 24 of the semiconductor substrate 20, the second dummy probe 620 may increase the signal-to-noise ratio (SNR) of the lower inspection portion 300 caused by charges on the upper surface 22 of the semiconductor substrate 20.

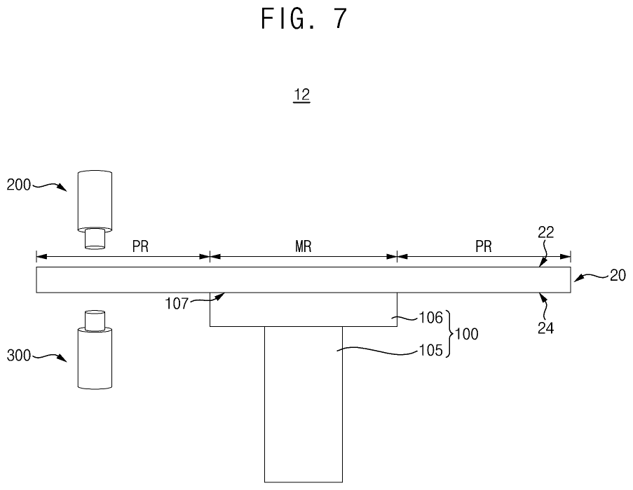

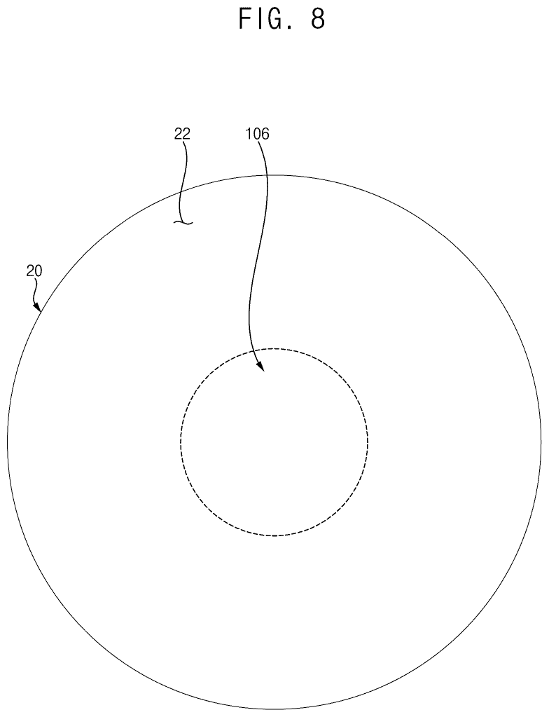

FIG. 7 is a cross-sectional view illustrating a substrate inspection apparatus in accordance with some example embodiments of the inventive concepts. FIG. 8 is a plan view illustrating a semiconductor substrate on a substrate support portion of FIG. 7. The substrate inspection apparatus may be substantially the same as or similar to the substrate inspection apparatus described with reference to FIGS. 1 to 5 except for a configuration of a substrate support portion. Thus, same reference numerals will be used to refer to the same or like elements and any further repetitive explanation concerning the above elements will be omitted.

Referring to FIGS. 7 and 8, a substrate support portion 100 of a substrate inspection apparatus 12 may include a support plate 106 having a mounting surface 107 on which a semiconductor substrate 20 is supported.

In some example embodiments, the support plate 106 may be fixedly connected to one end portion of the support shaft 105. A plurality of vacuum holes (not shown) may be provided in the mounting surface 107 of the support plate 106 to apply vacuum pressure in order to temporarily fix the semiconductor substrate 20. The plurality of vacuum holes may be respectively connected to a plurality of vacuum inlet lines (not shown) provided in the support shaft 105, and the vacuum inlet lines may be connected to a vacuum generator (not shown) to receive the vacuum pressure.

Since the support plate 106 supports a central region MR of a lower surface 24 of the semiconductor substrate 20, a peripheral region PR of the lower surface 24 of the semiconductor substrate 20 may be exposed. The upper inspection portion 200 may obtain an upper charge sensing value over the entire upper surface 22 of the semiconductor substrate 20. The lower inspection portion 300 may obtain a lower charge sensing value from the peripheral region PR of the lower surface 24 of the semiconductor substrate 20.

Hereinafter, a method of measuring a charge on a substrate surface using the substrate inspection apparatuses will be described.

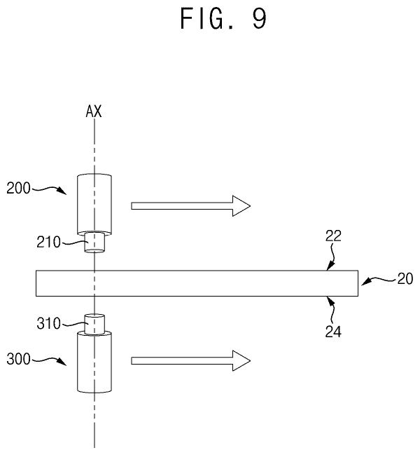

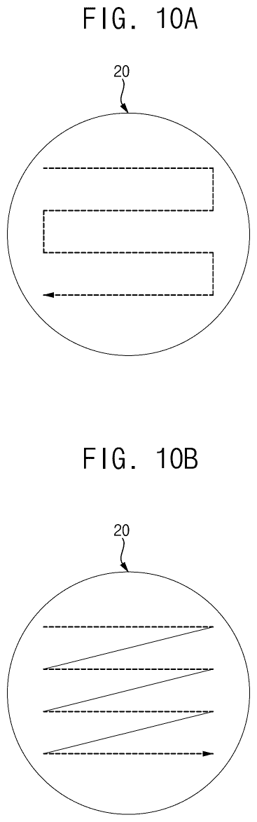

FIG. 9 is a cross-sectional view illustrating a substrate inspection method in accordance with some example embodiments of the inventive concepts. FIGS. 10A and 10B are plan views illustrating a scan direction in the substrate inspection method of FIG. 9. The substrate inspection method may measure charges on a substrate surface using the substrate inspection apparatus of FIG. 1.

Referring to FIGS. 9 to 10B, an upper inspection portion 200 and a lower inspection portion 300 may simultaneously measure an upper surface charge and a lower surface charge from an upper surface 22 and a lower surface 24 of a semiconductor substrate 20 while moving along the same scan direction.

As illustrated in FIG. 9, a lower probe 310 may be provided on the same axis AX as the upper probe. A substrate support portion supporting the semiconductor substrate 20 may move in a horizontal direction while the upper probe 210 and the lower probe 310 are fixed at preset positions. The upper inspection portion 200 and the lower inspection portion 300 may measure the upper surface charge and the lower surface charge from the semiconductor substrate 20 while moving in the horizontal direction.

Alternatively, while the substrate support portion supporting the semiconductor substrate 20 is fixed at a preset position, the upper probe 210 and the lower probe 310 may move in the horizontal direction. The upper inspection portion 200 and the lower inspection portion 300 may move in the horizontal direction and measure the upper surface charge and the lower surface charge from the semiconductor substrate 20.

As illustrated in FIGS. 10A and 10B, the upper probe 210 and the lower probe 310 may measure the upper surface charge and the lower surface charge of the semiconductor substrate 20 along a predetermined scanning direction. The semiconductor substrate 20 may be partitioned into local detection fields according to probe diameters and sensing electrode diameters of the of the upper inspection portion 200 and the lower inspection portion 300, and then, the scanning direction and scanning order of the local detection fields may be determined.

As illustrated in FIG. 10A, firstly, a top row of the detection fields may be scanned from the leftmost field to the rightmost field, and when the scanning of the top row of the fields, a second uppermost row of the fields may be scanned from the rightmost field to the leftmost field. When the scanning of the second uppermost row of the fields, a third uppermost row of the fields may be scanned from the leftmost field to the rightmost field. In this way, the entire surface of the semiconductor substrate 20 may be scanned in a meander shape starting from the top row.

As illustrated in FIG. 10B, firstly, a top row of the detection fields may be scanned from the leftmost field to the rightmost field, and when the scanning of the top row of the fields, a second uppermost row of the fields may be scanned from the leftmost field to the rightmost field. When the scanning of the second uppermost row of the fields, a third uppermost row of the fields may be scanned from the leftmost field to the rightmost field. In this way, the entire surface of the semiconductor substrate 20 may be scanned in a zigzag shape starting from the top row.

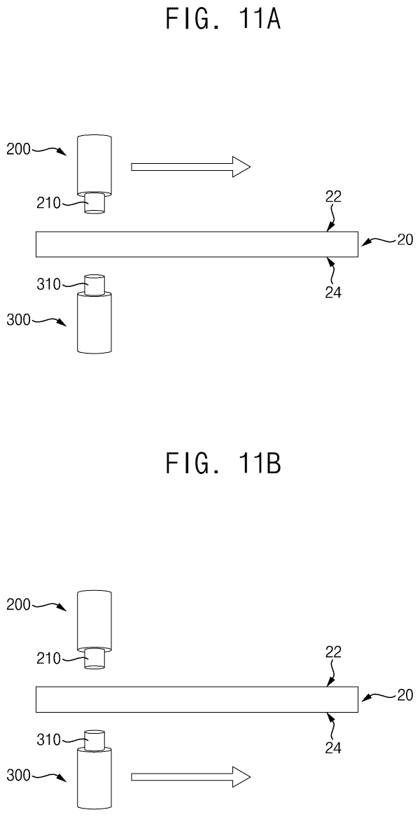

FIGS. 11A and 11B are cross-sectional views illustrating a substrate inspection method in accordance with some example embodiments of the inventive concepts. The substrate inspection method may be performed to measure a substrate surface charge using the substrate inspection apparatus of FIG. 1.

Referring to FIGS. 11A and 11B, an upper inspection portion 200 and a lower inspection portion 300 may independently measure an upper surface charge and a lower surface charge from an upper surface 22 and a lower surface 24 of the semiconductor substrate 20. When measuring the surface charge of the semiconductor substrate 20, a lower probe 310 may not be provided on a same axis as an upper probe 210.

As illustrated in FIG. 11A, the upper inspection portion 200 may measure the upper surface charge from the upper surface 22 of the semiconductor substrate 20 while moving along a first scanning direction. At this time, the lower inspection portion 300 may not perform an inspection operation. The first scanning direction may have a meander shape or a zigzag shape.

As illustrated in FIG. 11B, the lower inspection portion 300 may measure the lower surface charge from the lower surface 24 of the semiconductor substrate 20 while moving along a second scanning direction. At this time, the upper inspection portion 200 may not perform an inspection operation. The second scanning direction may have a meander shape or a zigzag shape. The second scanning direction may be the same as or different from the first scanning direction.

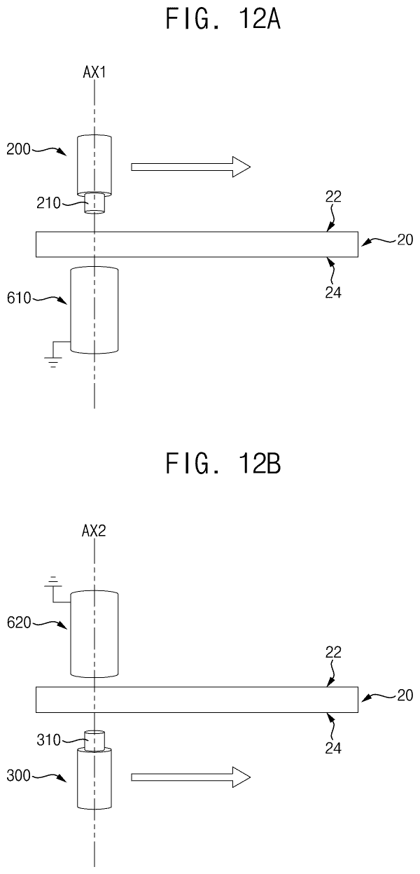

FIGS. 12A and 12B are cross-sectional views illustrating a substrate inspection method in accordance with some example embodiments of the inventive concepts. The substrate inspection method may be performed to measure a substrate surface charge using the substrate inspection apparatus of FIG. 6.

Referring to FIGS. 12A and 12B, an upper inspection portion 200 and the lower inspection portion 300 may independently measure an upper surface charge and a lower surface charge from an upper surface 22 and a lower surface 24 of a semiconductor substrate 20. When the upper inspection portion 200 measures the upper surface charge from the upper surface 22 of the semiconductor substrate 20, a first dummy probe 610 may be provided on the same axis AX1 as an upper probe 210. When the lower inspection portion 300 measures the lower surface charge from the lower surface 24 of the semiconductor substrate 20, a second dummy probe 620 may be provided on the same axis AX2 as a lower probe 310.

As illustrated in FIG. 12A, when the upper inspection portion 200 moves along a first scanning direction and measures the upper surface charge from the upper surface 22 of the semiconductor substrate 20, the first dummy probe 610 may move along the first scanning direction together with the upper probe 210. The first scanning direction may have a meander shape or a zigzag shape.

As illustrated in FIG. 12B, when the lower inspection portion 300 moves along a second scanning direction and measures the lower surface charge from the lower surface 24 of the semiconductor substrate 20, the second dummy probe 620 may move along the second scanning direction together with the lower probe 310. The second scanning direction may have a meander shape or a zigzag shape. The second scanning direction may be the same as or different from the first scanning direction.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the inventive concepts. Accordingly, all such modifications are intended to be included within the scope of example embodiments as defined in the claims.

What is claimed is:

1. A substrate inspection apparatus, comprising:
a substrate support portion configured to fixedly hold a semiconductor substrate, an upper surface and a lower surface of the semiconductor substrate are exposed while the semiconductor substrate is fixedly held by the substrate support portion;
an upper inspection portion including an upper probe having a first end portion spaced apart from the upper surface, and the upper probe including an upper charge sensor in the first end portion, the upper charge sensor configured to obtain an upper surface charge sensing value from the upper surface; and
a lower inspection portion including a lower probe having a second end portion spaced apart from the lower surface, and the lower probe including a lower charge sensor in the second end portion, the lower charge sensor configured to obtain a lower surface charge sensing value from the lower surface.

2. The substrate inspection apparatus of claim 1, wherein the upper inspection portion further includes an upper distance sensor configured to measure a distance between the upper surface and the upper charge sensor, and
the lower inspection portion further includes a lower distance sensor configured to measure a distance between the lower surface and the lower charge sensor.

3. The substrate inspection apparatus of claim 1, further comprising:
a controller configured to receive the upper surface charge sensing value and the lower surface charge sensing value from the upper inspection portion and the lower inspection portion respectively, and to correct the lower surface charge sensing value based on the upper surface charge sensing value and to correct the upper surface charge sensing value based on the lower surface charge sensing value.

4. The substrate inspection apparatus of claim 1, further comprising:
a driving portion configured to relatively move the substrate support portion between the upper probe and the lower probe.

5. The substrate inspection apparatus of claim 1, wherein the upper charge sensor is in a first central region of the first end portion, and
the lower charge sensor is in a second central region of the second end portion.

6. The substrate inspection apparatus of claim 5, wherein the upper charge sensor is in a first cavity in the first central region of the first end portion, and
the lower charge sensor is in a second cavity in the second central region of the second end portion.

7. The substrate inspection apparatus of claim 5, wherein the first end portion has a first dummy region surrounding the first central region,
the second end portion has a second dummy region surrounding the second central region, and
the first end portion and the second end portion have curvature shape in the first dummy region and the second dummy region, respectively.

8. The substrate inspection apparatus of claim 1, wherein the lower probe is on a same axis as the upper probe.

9. The substrate inspection apparatus of claim 1, wherein the first end portion is spaced apart from the upper surface by a first distance,
the second end portion is spaced apart from the lower surface by a second distance, and
each of the first distance and the second distance is within a range of 10 μm to 5 mm.

10. The substrate inspection apparatus of claim 1, wherein the first end portion has a first diameter,
the second end portion has a second diameter, and
each of the first diameter and the second diameter is within a range of 1 mm to 30 mm.

11. A substrate inspection apparatus, comprising:
a substrate support portion configured to fixedly hold an outer surface of a semiconductor substrate, an upper surface and a lower surface of the semiconductor substrate are exposed while the semiconductor substrate is fixedly held by the substrate support portion;
an upper inspection portion including an upper probe having a first end portion spaced apart from the upper surface, and the upper probe including an upper charge sensor in a first central region of the first end portion, the upper charge sensor configured to obtain an upper surface charge sensing value from the upper surface;
a lower inspection portion including a lower probe having a second end portion spaced apart from the lower surface, and the lower probe including a lower charge sensor in a second central region of the second end portion, the lower charge sensor configured to obtain a lower surface charge sensing value from the lower surface; and
a driving portion configured to relatively move the substrate support portion between the upper probe and the lower probe.

12. The substrate inspection apparatus of claim 11, wherein the upper inspection portion further includes an upper distance sensor configured to measure a distance between the upper surface and the upper charge sensor, and
the lower inspection portion further includes a lower distance sensor configured to measure a distance between the lower surface and the lower charge sensor.

13. The substrate inspection apparatus of claim 11, further comprising:
a controller configured to receive the upper surface charge sensing value and the lower surface charge sensing value from the upper inspection portion and the lower inspection portion respectively, and to correct the lower surface charge sensing value based on the upper surface charge sensing value and to correct the upper surface charge sensing value based on the lower surface charge sensing value.

14. The substrate inspection apparatus of claim 11, wherein the upper charge sensor is in a first cavity in the first central region of the first end portion, and
the lower charge sensor is in a second cavity in the second central region of the second end portion.

15. The substrate inspection apparatus of claim 11, wherein the first end portion has a first dummy region surrounding the first central region,
the second end portion has a second dummy region surrounding the second central region, and
the first end portion and the second end portion have curvature shape in the first dummy region and the second dummy region, respectively.

16. The substrate inspection apparatus of claim 11, wherein the substrate support portion includes a plurality of vacuum holes configured to provide vacuum pressure to secure the outer surface of the semiconductor substrate.

17. The substrate inspection apparatus of claim 11, wherein the first end portion is spaced apart from the upper surface by a first distance,
the second end portion is spaced apart from the lower surface by a second distance, and
each of the first distance and the second distance is within a range of 10 μm to 5 mm.

18. The substrate inspection apparatus of claim 17, wherein the first distance and the second distance are equal to each other.

19. The substrate inspection apparatus of claim 11, wherein the first end portion has a first diameter,
the second end portion has a second diameter, and
each of the first diameter and the second diameter is within a range of 1 mm to 30 mm.

20. A substrate inspection apparatus, comprising:
a substrate support portion configured to fixedly hold an outer surface of a semiconductor substrate, an upper surface and a lower surface of the semiconductor substrate are exposed while the semiconductor substrate is fixedly held by the substrate support portion;
an upper inspection portion including
an upper probe having a first end portion spaced apart from the upper surface, the upper probe movable in a horizontal direction,
an upper distance sensor configured to measure a distance between the upper probe and the upper surface, and
an upper charge sensor in a first central region of the first end portion, the upper charge sensor configured to obtain an upper surface charge sensing value of the upper surface;
a lower inspection portion including
a lower probe having a second end portion spaced apart from the lower surface, the lower probe movable in the horizontal direction,
a lower distance sensor configured to measure a distance between the lower probe and the lower surface, and
a lower charge sensor in a second central region of the second end portion, the lower charge sensor configured to obtain a lower surface charge sensing value of the lower surface; and
a controller configured to receive and store the upper surface charge sensing value and the lower surface charge sensing value from the upper inspection portion and the lower inspection portion respectively.
